(19) United States
(12) Patent Application Publication
(10) Pub. No.: US 2006/0132002 A1
(43) Pub. Date: Jun. 22, 2006

(54) Piezoelectric actuator

(76) Inventor: Friedrich Boecking, Stuttgart (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 10/524,789

(22) PCT Filed: Jun. 2, 2003
(86) PCT No.: PCT/DE03/01799

§ 371 Date: Aug. 22, 2005

(30) Foreign Application Priority Data
Aug. 16, 2002 (DE) 102 37 588.7

(51) Int. Cl. H01L 41/083

(52) U.S. Cl. 310/367

(57) ABSTRACT

A piezoelectric actuator for actuating a mechanical component in which, with a multilayer construction of piezoelectric layers and inner electrodes disposed between them, an alternate-side lateral contacting of the inner electrodes with outer electrodes is possible. Before being put together to make the multilayer construction, the individual inner electrodes are rounded at the corners formed by the cut edges. The corners may each have a chamfer and the corners of the chamfers may each also be rounded.

### PRIOR ART

The invention relates to a piezoelectric actuator, for instance for actuating a mechanical component such as a valve or the like, as defined by the characteristics of the preamble to the main claim.

It is widely known that by using the so-called piezoelectric effect, a piezoelectric element may be constructed from a material that has a suitable crystal structure. When an external electrical voltage is applied, a mechanical reaction of the piezoelectric element ensues, which as a function of the crystal structure and the regions where the electrical voltage is applied represents a pressure or tension in a predeterminable direction.

The construction of this piezoelectric actuator as a so-called multilayer actuator may, as described for instance in German Patent Disclosure DE 199 28 191 A1, be done in multiple layers; the electrodes by way of which the electrical voltage is applied are each disposed between the layers. In operation of the piezoelectric actuator, care must be taken to assure that no interfering cracks form as a result of mechanical stresses in the layer construction.

Upon an alternate-side lateral contacting of the electrodes, the electrodes may as a rule not always be extended all the way to the opposite side, because otherwise voltage sparkovers can cause the destruction of the piezoelectric actuator. The alternate-side contacting is constructed such that each two inner electrodes are contacted jointly on one side in the layer construction and include an inner electrode of different polarity that is contacted on the opposite side. In alternation, one of these jointly contacted inner electrodes in the layer construction is then made not to extend all the way to the end of the piezoelectric layers, thus forming a neutral phase, while the other one made to extend all the way to the end of the piezoelectric layer.

The design of the inner electrodes is as a rule selected as a function of the required external shape of the piezoelectric actuator; most actuator shapes also depend on the manufacturing technique and on the cutting of the actuator stack. Since voltage sparkovers can easily occur at the edges produced by the cut, machining of the edges is often necessary, but especially if it is performed afterward on the actuator, this can be very complicated and expensive.

### ADVANTAGES OF THE INVENTION

The piezoelectric actuator described at the outset, which may be used for instance for actuating a mechanical component, is advantageously constructed with a multilayer construction of piezoelectric layers and inner electrodes between the piezoelectric layers. According to the invention, the individual inner electrodes, already before being assembled into the multilayer construction, are rounded at the corners formed by the cut edges.

If the corners each have a chamfer, then in a simple way the corners of the chamfers can each also be rounded. In this respect it is especially advantageous if the rounded features each have a rounding radius of at least 20 μm, so as not to act as a pointed tip or as an edge. With the invention, it is then possible in a simple way to dispense with machining the edge of the piezoelectric actuator, since such machining, especially for producing rounded features afterward, would be complicated and expensive.

### DRAWING

Exemplary embodiments of the piezoelectric actuator of the invention will be described in conjunction with the drawing. Shown are:

FIG. 1, a section through a piezoelectric actuator of the prior art, with a multilayer construction made up of layers of piezoelectric ceramic and with alternating-side-contacted inner electrodes and undulating outer electrodes;

FIG. 2, a detail of the inner electrodes with rounded corners;

FIG. 3, a detail of the inner electrodes with rounded corners that have already been chamfered; and

FIG. 4, a further exemplary embodiment of an inner electrode designed with rounded corners or edges.

### DESCRIPTION OF THE EXEMPLARY EMBODIMENTS

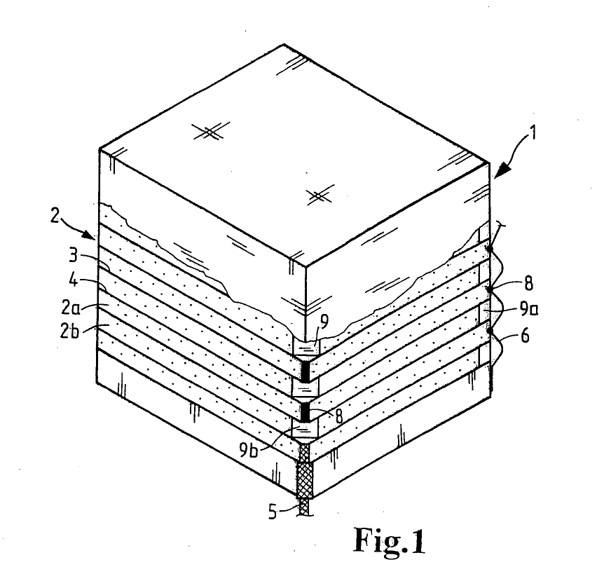

In FIG. 1, a piezoelectric actuator 1 is shown which is constructed in a manner per se of piezoelectric films 2 of a quartz material having a suitable crystal structure, so that by using what is known as the piezoelectric effect, when an external electrical voltage is applied to inner electrodes 3 and 4, shown only schematically here, via externally contacted outer electrodes 5 and 6, a mechanical reaction of the piezoelectric actuator 1 ensues.

It can also be seen from FIG. 1 that the outer electrodes 5 and 6 are embodied as undulating electrodes, which are each contacted at contact faces 8 by two inner electrodes that have the same polarity. The piezoelectric layers 2 or 2a, 2b are each offset inward in alternation at the corners in a predetermined region, creating a respective groove 9 or 9a, 9b.

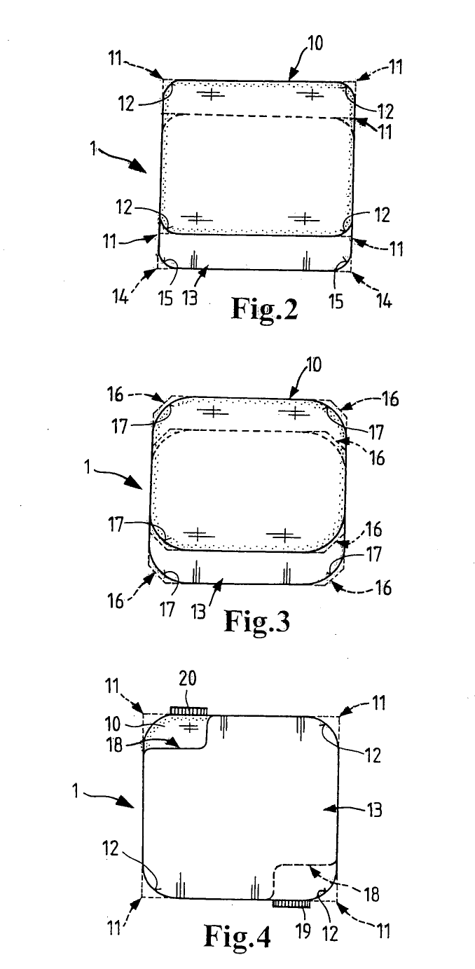

It can be seen from FIG. 2 that according to the invention, an inner electrode 10 is provided, on each of its corners 11 shown in dashed lines, with a respective rounded feature 12. The inner electrode 13, mounted offset for the alternate-side contacting, is provided with rounded features 15 on each of its corners 14.

In FIG. 3, an embodiment is shown in which the already existing chamfers 16 at the corners of the inner electrode 10 have also already been provided with a rounded feature 17. The same is true for chamfers 16 at the corners of the inner electrode 13 in FIG. 3.

From FIG. 4, still another exemplary embodiment of a design for the inner electrodes 10 and 13 can be seen, in which in addition to the rounded features 12, rounded neutral regions 18 are each recessed out on alternate sides, so that outer electrodes 19 and 20 can be mounted.

1-4. (canceled)

5. In a piezoelectric actuator, comprising
a multilayer construction of piezoelectric layers (2) having corners defined by cut edges and inner electrodes (3, 4; 10, 13) disposed between the piezoelectric layers, and
an alternate-side lateral contacting of the inner electrodes (3, 4; 10, 13) with outer electrodes (9; 19, 20), the improvement wherein
the individual inner electrodes (10, 13) are rounded at the corners (11) formed by the cut edges.

6. The piezoelectric actuator according to claim 5, wherein
the corners (11) each have a chamfer (16); and wherein the corners of the chamfers are each rounded.

7. The piezoelectric actuator according to claim 5, wherein
the rounded features (12; 17) each have a rounding radius of at least 20 μm.

8. The piezoelectric actuator according to claim 6, wherein
the rounded features (12; 17) each have a rounding radius of at least 20 μm.

9. The piezoelectric actuator according to claim 5, wherein
the piezoelectric actuator (1) can be used for actuating a mechanical component, such as a valve or the like.

10. The piezoelectric actuator according to claim 6, wherein
the piezoelectric actuator (1) can be used for actuating a mechanical component, such as a valve or the like.

11. The piezoelectric actuator according to claim 7, wherein
the piezoelectric actuator (1) can be used for actuating a mechanical component, such as a valve or the like.

12. The piezoelectric actuator according to claim 8, wherein
the piezoelectric actuator (1) can be used for actuating a mechanical component, such as a valve or the like.
